(19) United States
(12) Patent Application Publication
(10) Pub. No.: US 2026/0229842 A1
(43) Pub. Date: Aug. 6, 2026

(54) Optical transmitter

(71) Applicant: Innolume GmbH, Dortmund (DE)

(72) Inventors: Vasilii Belykh, Dortmund (DE); Alexey Gubenko, Dortmund (DE); Alexey Kovsh, Dortmund (DE); Aleksei Borodkin, Dortmund (DE); Artem Petrenko, Dortmund (DE)

(21) Appl. No.: 19/046,170

(22) Filed: Feb. 5, 2025

(51) Int. Cl. H01S 5/125; H01S 5/00; H01S 5/026; H01S 5/34; H01S 5/343; H01S 5/40

(52) U.S. Cl. CPC H01S 5/125; H01S 5/0085; H01S 5/026; H01S 5/341; H01S 5/34313; H01S 5/4087

(57) ABSTRACT

According to an embodiment, an optical transmitter comprises: a laser configured to provide an optical signal to an optical output based on a control current; a control unit electrically coupled to the laser and configured to modulate the laser using the control current, wherein the control current comprises a direct current component and a temporally varying modulation component configured to cause a temporal variation of a wavelength of at least one spectral line in the optical signal; a semiconductor optical amplifier comprising an optical input and an optical output, wherein the semiconductor optical amplifier is configured to receive the optical signal from the optical output of the laser, amplify the optical signal while operating in a saturation mode, and provide the amplified optical signal to an optical output of the semiconductor optical amplifier; and an optical fiber interface optically coupled to the optical output of the semiconductor optical amplifier.

### TECHNICAL FIELD

The present disclosure relates to the field of optics, and more particularly to an optical transmitter and a method for transmitting an optical signal.

### BACKGROUND

In many applications, the amount of optical power that can be transmitted via an optical fiber is limited by Brillouin scattering. This can, for example, limit the maximum transmission distance in fiber-optic communications. Brillouin scattering can also be a limiting factor in other applications, such as in seeding of high-power lasers.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

It is an object to provide an optical transmitter and a method for transmitting an optical signal. The foregoing and other objects are achieved by the features of the independent claims. Further implementation forms are apparent from the dependent claims, the description and the figures.

According to a first aspect, an optical transmitter comprises a laser comprising an optical output and configured to provide an optical signal to the optical output based on a control current; a control unit electrically coupled to the laser and configured to modulate the laser using the control current, wherein the control current comprises a direct current component and a temporally varying modulation component configured to cause a temporal variation of a wavelength of at least one spectral line in the optical signal; a semiconductor optical amplifier comprising an optical input and an optical output, wherein the optical input of the semiconductor optical amplifier is optically coupled to the optical output of the laser and the semiconductor optical amplifier is configured to receive the optical signal from the optical output of the laser, amplify the optical signal while operating in a saturation mode, and provide the amplified optical signal to the optical output of the semiconductor optical amplifier; and an optical fiber interface optically coupled to the optical output of the semiconductor optical amplifier.

In an implementation form of the first aspect, the laser comprises a single-mode laser.

In another implementation form of the first aspect, the laser comprises a semiconductor laser.

In another implementation form of the first aspect, the laser comprises a distributed feedback laser or a Fabry-Pérot laser.

In another implementation form of the first aspect, the laser comprises an active region comprising at least one of: quantum wells, quantum dots, quantum wires, or/and quantum dashes.

In another implementation form of the first aspect, the laser comprises an active region based on quantum well and/or quantum dot layers realized in III-V material composition.

In another implementation form of the first aspect, the semiconductor optical amplifier comprises an active region based on quantum dots embedded in quantum wells and realized in III-V material composition.

In another implementation form of the first aspect, the laser comprises an active region comprising indium arsenide quantum dots embedded in indium gallium arsenide quantum wells.

In another implementation form of the first aspect, the semiconductor optical amplifier comprises an active region comprising indium arsenide quantum dots embedded in indium gallium arsenide quantum wells.

In another implementation form of the first aspect, the laser further comprises a distributed Bragg reflector.

In another implementation form of the first aspect, the laser and the semiconductor optical amplifier are monolithically integrated.

In another implementation form of the first aspect, the optical transmitter further comprises an optical isolator optically coupled to the optical output of the laser and the optical input of the semiconductor optical amplifier.

In another implementation form of the first aspect, the laser comprises a comb laser configured to provide a plurality of spectral lines of different wavelengths in the optical signal.

In another implementation form of the first aspect, the temporally varying modulation component comprises a sinusoidal component or a sawtooth component.

In another implementation form of the first aspect, the control unit is further electrically coupled to the semiconductor optical amplifier and configured to modulate the semiconductor optical amplifier using a second control current, wherein the second control current comprises a second direct current component and a second temporally varying modulation component, wherein the temporally varying modulation component has a first phase and the second temporally varying modulation component has a second phase, opposite to the first phase.

In another implementation form of the first aspect, the optical transmitter further comprises: a laser array comprising the laser, wherein each laser in the laser array comprises an optical output and is configured to provide an optical signal to the optical output of the laser based on a corresponding control current and each optical signal comprises a spectral line of different wavelength; and an optical combiner comprising a plurality of optical inputs and an optical output, wherein each optical input in the plurality of optical inputs is optically coupled to the optical output of a corresponding laser in the laser array and the optical output of the optical combiner is optically coupled to the optical input of the semiconductor optical amplifier; wherein the control unit electrically coupled to each laser in the laser array and configured to modulate each laser in the laser array using a corresponding control current, wherein each control current comprises a direct current component and a temporally varying modulation component configured to cause a temporal variation of the wavelength of the spectral line in the corresponding optical signal.

According to a second aspect, a method for transmitting an optical signal comprises: modulating a laser using a control current, wherein the control current comprises a direct current component and a temporally varying modulation component causing a temporal variation of a wavelength of at least one spectral line in an optical signal emitted by the laser; providing the optical signal to a semiconductor optical amplifier; amplifying the optical signal using the semiconductor optical amplifier while operating the semiconductor optical amplifier in a saturation mode; and providing the amplified optical signal to an optical fiber interface.

In an implementation form of the second aspect, the method further comprises: modulating the semiconductor optical amplifier using a second control current, wherein the second control current comprises a second direct current component and a second temporally varying modulation component, wherein the temporally varying modulation component has a first phase and the second temporally varying modulation component has a second phase, opposite to the first phase.

Many of the attendant features will be more readily appreciated as they become better understood by reference to the following detailed description considered in connection with the accompanying drawings.

### DESCRIPTION OF THE DRAWINGS

In the following, example embodiments are described in more detail with reference to the attached figures and drawings, in which:

FIG. 1 illustrates a schematic representation of an optical transmitter according to an embodiment;

FIG. 2 illustrates a schematic representation of a spectrum of a laser according to an embodiment;

FIG. 3 illustrates a schematic representation of a temporal variation of an intensity of an optical signal according to an embodiment;

FIG. 4 illustrates a schematic representation of a temporal variation of an intensity of an optical signal according to another embodiment;

FIG. 5 illustrates a schematic representation of an optical transmitter according to another embodiment;

FIG. 6 illustrates a schematic representation of an optical transmitter according to another embodiment;

FIG. 7 illustrates a schematic representation of an optical transmitter according to another embodiment;

FIG. 8 illustrates a schematic representation of an optical transmitter according to another embodiment;

FIG. 9 illustrates a schematic representation of a spectrum of a laser according to another embodiment;

FIG. 10 illustrates a schematic representation of a semiconductor structure according to another embodiment;

FIG. 11 illustrates a flow chart representation of a method for transmitting an optical signal according to an embodiment;

FIG. 12 illustrates a schematic representation of exemplary measurement results;

FIG. 13 illustrates a schematic representation of exemplary measurement results;

FIG. 14 illustrates a schematic representation of exemplary measurement results; and

FIG. 15 illustrates a schematic representation of exemplary measurement results.

In the following, identical reference signs refer to similar or at least functionally equivalent features.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilized, and structural or logical changes may be made without departing from the scope of the present disclosure. The following detailed description, therefore, is not to be taken in a limiting sense, as the scope of the present disclosure is defined by the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

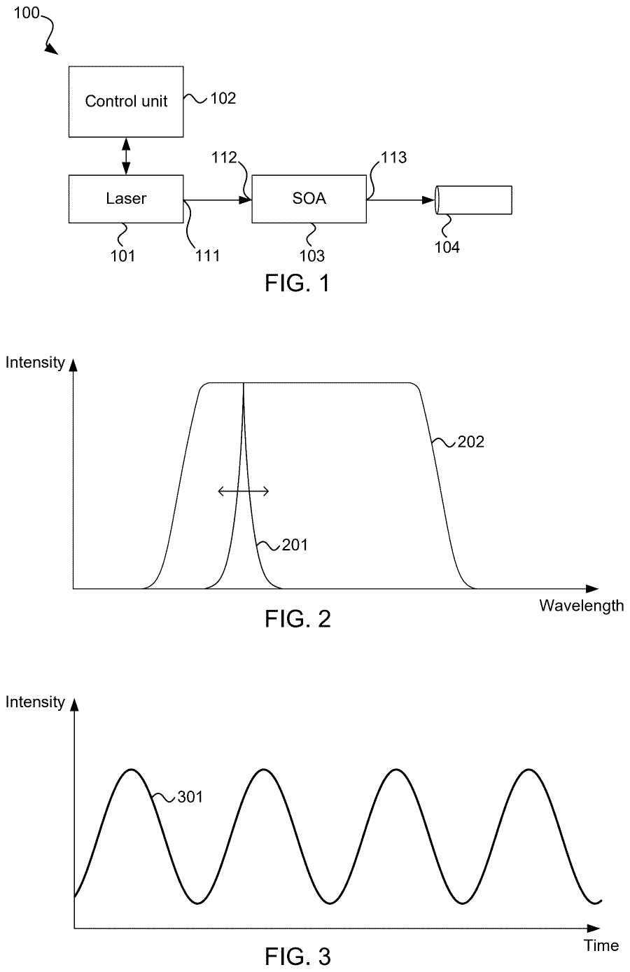

FIG. 1 illustrates a schematic representation of an optical transmitter according to an embodiment.

According to an embodiment, an optical transmitter 100 comprises a laser 101 comprising an optical output 111 and configured to provide an optical signal to the optical output 111 based on a control current.

The control current may comprise, for example, a current applied to the laser 101 that can cause lasing conditions at an active region of the laser 101. Thus, the control current can control lasing of the laser 101.

The laser 101 may also be referred to as a laser diode or similar.

The optical transmitter 100 may further comprise control unit 102 electrically coupled to the laser 101 and configured to modulate the laser 101 using the control current, wherein the control current comprises a direct current component and a temporally varying modulation component configured to cause a temporal variation of a wavelength of at least one spectral line in the optical signal.

The control unit 102 may comprise, for example, a computing device or any other electronic device capable of providing the control current to the laser 101.

For example, the control unit 102 may comprise at least one processor and at least one memory including computer program code. The at least one memory and the computer program code can be configured to, with the at least one processor, cause the control unit 102 to perform the functionality disclosed herein. The control unit 102 may further comprise other components, such as one or more current sources, one or more modulators for generating different waveforms. Components of the control unit 102 may be controlled by the at least one processor.

The control unit 102 may be electrically coupled to the laser 101. The control unit 102 may provide the control current to the laser 101 via the electrical coupling.

The direct current component may refer to a component of the control current that is substantially constant. The temporally varying modulation component may refer to a component of the control current that varies as a function of time. The control current may comprise, for example, a sum of the direct current component and the temporally varying modulation component.

Herein, a spectral line may also be referred to as an optical line, a wavelength peak, a peak wavelength, an optical mode, a longitudinal optical mode, a laser longitudinal mode, a laser longitudinal optical mode, or similar.

Herein, when two components/parts are optically coupled, optical signals can be transmitted between the components/parts.

The control current may refer to an electrical current provided by the control unit 102 to the laser 101.

The temporal variation of a wavelength of at least one spectral line in the optical signal may be referred to as frequency modulation.

In some embodiments, the control current may also cause temporal variation of an amplitude of at least one spectral line in the optical signal. This may be referred to as amplitude modulation.

The optical transmitter 100 may further comprise semiconductor optical amplifier (SOA) 103 comprising an optical input 112 and an optical output 113, wherein the optical input 112 of the semiconductor optical amplifier 103 is optically coupled to the optical output 111 of the laser 101 and the semiconductor optical amplifier 103 is configured to receive the optical signal from the optical output 111 of the laser 101, amplify the optical signal while operating in a saturation mode, and provide the amplified optical signal to the optical output 113 of the semiconductor optical amplifier 103.

The SOA 103 is an optical amplifier based on a semiconductor gain medium, also referred to as an active region. The SOA 103 can amplify optical signal when the active region is biased with a bias current.

According to an embodiment, a length of an optical cavity of the SOA 103 is in the range of 0.5-8 mm.

The saturation mode of the SOA 103 may refer to an operation regime of the SOA 103 in which the gain of the SOA 103 is reduced for greater input optical powers. For example, the gain of the SOA 103 may be substantially constant for input optical powers less than a saturation power. For input optical powers greater than the saturation power, the gain of the SOA 103 may be less than for input optical powers less than the saturation power.

The SOA 103 may be biased via, for example, a bias current/voltage applied to the SOA 103. The bias current/voltage may be provided by, for example, the control unit 102 or by some other current/voltage source. The SOA 103 may be operated in the saturation mode by, for example, providing a sufficient optical power to the SOA input 112. This optical power should be comparable or larger than saturation input power of the SOA 103. The saturation input power depends on the design of the SOA 130. The saturation mode of the SOA 103 also can be controlled by a current/voltage applied to the SOA 103.

Since the SOA 103 is operating in the saturation mode, the SOA 103 can be utilized to amplify the optical signal and reduce amplitude fluctuations of the optical signal. Since the gain of the SOA 103 can be less for larger input optical powers due to the saturation mode, parts of the optical signal that have a large intensity can experience less gain and can thus be amplified less by the SOA 103 than parts of the optical signal that have a smaller intensity.

The optical transmitter 100 may further comprise optical fiber interface 104 optically coupled to the optical output of the semiconductor optical amplifier 103.

The optical fiber interface 104 may comprise any interface that can be optically coupled to an optical fiber. For example, the optical fiber interface 104 may comprise an optical fiber connector, a fiber coupler, or similar that can be used to optically coupled the optical transmitter 100 to an optical fiber.

According to an embodiment, the laser 101 comprises a single-mode laser.

Herein, a single-mode laser may refer to a laser that emits light in a single longitudinal mode. Thus, a single-mode laser may emit light at a single, well-defined frequency/wavelength band with minimal spectral spreading.

According to an embodiment, the laser 101 comprises a semiconductor laser.

According to an embodiment, the laser 101 comprises a distributed feedback (DFB) laser or a Fabry-Pérot laser.

Herein, a distributed feedback laser may refer to a laser comprising an interference grating, such as a surface-corrugated grating, that provides optical feedback for the laser 101. For example, the light can be generated in one stack of layers, such as quantum dots, of the laser 101 and the surface-corrugated grating can be located in upper layers of the laser 101. The surface-corrugated grating can create a distributed cavity for the laser 101.

Herein, a Fabry-Pérot laser may refer to a laser comprising an active region in a Fabry-Pérot cavity that provides optical feedback for the laser.

Herein, an active region of the laser 101 and/or of the SOA 103 may also be referred to as a gain region, a gain medium, an active layer, or similar.

Since the temporally varying modulation component is configured to cause a temporal variation of a wavelength of at least one spectral line in the optical signal, the optical power emitted by the laser can be spread to a larger wavelength range. Further, the SOA 103 operating in the saturation mode can amplify the optical signal and reduce amplitude fluctuations in the optical signal. Therefore, the optical transmitter 100 can transmit a high-power optical signal while Brillouin scattering in the optical fiber can be reduced as a result of the laser frequency modulation.

The amplified optical signal can be used to, for example, seed high-power lasers.

The amplified optical signal can be used for, for example, high-distance data transmission. A conventional solution to increase the distance at which a transceiver can transmit data may be to, for example, increase the sensitivity of the detector, by for example replacing a p-type-intrinsic-n-type (PIN) photodiode with an avalanche photodiode (APD). Instead, the power of the transmitter can be increased.

An optical power above 5 milliwatts (mW) per spectral line can lead to high Brillouin scattering and thus to absorption. The optical transmitter 100 can allow to input, for example, an optical signal with greater than 100 mW of power into an optical fiber.

For example, the output optical power of the optical transmitter 100 can be up to 170 mW.

Due to the saturation regime of the SOA 103, the intensity modulation can be less than the relative intensity noise (RIN) and therefore no significant additional noise may be induced to the optical link.

FIG. 2 illustrates a schematic representation of a spectrum of a laser according to an embodiment.

The temporally varying modulation component can be configured to cause a temporal variation of a wavelength of at least one spectral line in the optical signal.

Herein, a spectral line may refer to a narrow intensity peak in the optical spectrum emitted by a device, such as the laser 101 and/or the SOA 103.

The embodiment of FIG. 2 illustrates an example of a spectrum of the optical output 111 of the laser 101. The spectrum of the laser 101 comprises a spectral line 201. When the laser 101 is modulated using the control current, the temporally varying modulation component causes the spectral line 201 to move as illustrated by the arrows in FIG. 2.

The embodiment of FIG. 2 further illustrates an envelope 202 of the spectrum of the laser 101. The envelope 202 can correspond to, for example, a temporal average of the spectrum of the laser 101 over one or more periods of the temporally varying modulation component. As the temporally varying modulation component varies over time, the spectral line 201 moves and thus the envelope 202 is formed. Thus, with the varying modulation component, broadening of the spectrum of the laser 101 can be achieved. This may also be referred to as increasing the optical bandwidth of the optical transmitter 100.

For example, a 100 kilohertz (kHz) temporally varying modulation component can cause a 100 gigahertz (GHz) or greater variation in the optical frequency of at least one spectral line in the optical signal.

FIG. 3 illustrates a schematic representation of a temporal variation of an intensity of an optical signal according to an embodiment.

According to an embodiment, the temporally varying modulation component comprises a sinusoidal component or a sawtooth component.

In other embodiments, the temporally varying modulation component may comprise any other type of temporal waveform.

For example, the embodiment of FIG. 3 illustrates a simplified example of the intensity of an optical signal emitted by the laser 101. Curve 301 corresponds to the intensity of the optical signal emitted by the laser 101. In the embodiment of FIG. 3, the temporally varying modulation component may comprise a sinusoidal component, which can be observed as a sinusoidal variation of the intensity of the optical signal emitted by the laser 101.

Since the spectrum emitted by the laser 101 varies over time, as illustrated by the embodiment of FIG. 2, the light emitted by the laser 101 can comprise different wavelengths in different amounts at different times depending on the temporally varying modulation component.

In other embodiments, the temporally varying modulation component may comprise a different type of signal. For example, sawtooth modulation signals, triangular modulation signals, square-wave modulation signals, and/or stepped modulation signals that can be used in frequency modulated continuous wave (FMCW) light detection and ranging (LIDAR) applications. A different temporally varying modulation component may cause a different type of variation of the intensity of the light emitted by the laser 101. The modulation of the spectrum of the light emitted by the optical transmitter 100 can be advantageous for LIDAR applications.

The temporally varying modulation component may comprise, for example, a radio frequency (RF) signal.

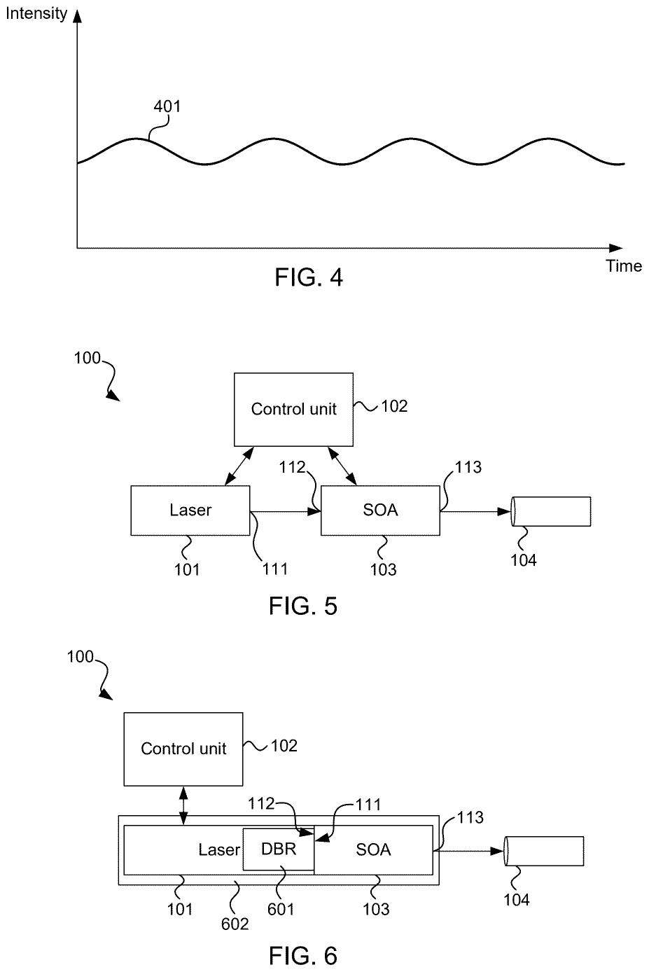

FIG. 4 illustrates a schematic representation of a temporal variation of an intensity of an optical signal according to another embodiment.

The embodiment of FIG. 4 illustrates an example of the temporal variation of the optical signal amplified by the SOA 103. Curve 401 corresponds to the intensity of an amplified optical signal emitted by the laser 101 and amplified by the SOA 103. Due to the SOA 103 operating in the saturation regime, the SOA 103 can reduce the temporal variation of the intensity of the optical signal. This can be observed by comparing FIG. 4 to FIG. 3.

FIG. 5 illustrates a schematic representation of an optical transmitter according to another embodiment.

According to an embodiment, the control unit 102 is further electrically coupled to the semiconductor optical amplifier 103 and configured to modulate the semiconductor optical amplifier 103 using a second control current, wherein the second control current comprises a second direct current component and a second temporally varying modulation component, wherein the temporally varying modulation component has a first phase and the second temporally varying modulation component has a second phase, opposite to the first phase.

The control current may also be referred to as a first control current. The direct current component may also be referred to as a first direct current component. The temporally varying modulation component may also be referred to as a first temporally varying modulation component.

The second control current may comprise, for example, a bias current applied to an active region of the SOA 103. Thus, the second control current can pump the active region and control the gain of the SOA 103.

By modulating the SOA 103 with the second temporally varying modulation component with the opposite phase to the modulation of the laser 101, intensity variation of the optical signal may be reduced further.

The first phase and the second phase can have, for example, a phase difference of substantially 180 degrees, such as 175-185 degrees, 177.5-182.5 degrees, 179-181 degrees, 179.5-180.5 degrees, 179.9-180.1 degrees, or 179.95-180.05 degrees.

FIG. 6 illustrates a schematic representation of an optical transmitter according to another embodiment.

According to an embodiment, the laser 101 further comprises a distributed Bragg reflector (DBR) 601.

In other embodiments, the laser 101 may comprise a DFB laser. In such embodiments, the DBR 601 may not be needed.

According to an embodiment, the laser 101 and the semiconductor optical amplifier 103 are monolithically integrated.

When the laser 101 and the semiconductor optical amplifier 103 are monolithically integrated, the optical transmitter 100 may further comprise a DBR as a part of the laser 101. Alternatively, the laser 101 may comprise a DFB laser. Since the laser 101 may not comprise a cleaved end between the laser 101 and the SOA 103 that functions as a mirror for the cavity of the laser 101 when the laser 101 and the SOA 103 are monolithically integrated, the DBR 601 may be needed.

For example, in the embodiment of FIG. 6, the laser 101 further comprises a DBR 601 as a part of the cavity of the laser 101 and the semiconductor optical amplifier 103 that are monolithically integrated thus forming a monolithically integrated photonic device 602.

For example, the laser 101 may comprise a DBR at one end of the active region of the laser 101. A resonant cavity of the laser 101 may be defined by a DBR at one end of the resonant cavity and a cleaved facet at the other end of the resonant cavity. The resonant cavity can comprise the active region, where a current, such as the control current, can be injected to produce a plurality of spatial lasing modes. Thus, a laser 101 comprising a DBR 601 may be used to implement a comb laser.

According to an embodiment, a length of an optical cavity of the laser 101 is in the range of 0.5-6 millimeters (mm).

A laser comprising a DBR may also be referred to as a DBR laser.

Herein, when the laser 101 and the SOA 103 are monolithically integrated, the laser 101 and the SOA 103 may be implemented on a common semiconductor material platform, such as gallium arsenide (GaAs) based material platform. For example, the optical transmitter 100 may be implemented using a plurality of semiconductor layers and the laser 101 and the SOA 103 may be implemented using a subset of layers in the plurality of semiconductor layers that are common for the laser 101 and the SOA 103. For example, an active region of the laser 101 and an active region of the SOA 103 may be implemented using the same layer or the same subset of layers in the plurality of semiconductor layers.

When the laser 101 and the SOA 103 are monolithically integrated, the laser 101 and the SOA 103 may be manufactured using a single growth process, one material platform, and be processed on a single wafer.

Herein, when the laser 101 and the SOA 103 are realized in GaAs and/or in a GaAs based material platform, GaAs may be used as the main material of the laser 101 and the SOA 103. For example, GaAs can be used as the substrate or some other material, such as other III-V semiconductor materials, can be used as the substrate, GaAs can be grown onto the substrate, for example epitaxially, and other structures of the laser 101 and the SOA 103 can be grown onto the GaAs. Such a semiconductor structure may comprise, for example, a semiconductor heterostructure comprising other materials grown on the GaAs. The other materials can comprise, for example, aluminum arsenide (AlAs), indium gallium arsenide (InGaAs), aluminum gallium arsenide (AlGaAs) and/or indium arsenide (InAs).

With monolithic integration, the laser 101 and the SOA 103 may be implemented on a single photonic chip.

With monolithic integration, it may be possible to achieve a large wavelength variation of the at least one spectral line, such as up to 100 GHz, when recalculated of frequency, or greater, due to the modulation while the oscillations in intensity can be low and occur at frequencies up to few tens of MHz.

The optical output 111 of the laser 101 may be implemented, for example, as an optical output facet that lies on an optical interface edge. The optical input 112 of the SOA 103 may be implemented as an optical input facet that lies on the optical interface edge.

A “facet” may refer to a transmitting or receiving area on a surface for transmitting and/or receiving optical signals, respectively. The optical signal emitted by the laser 101 may thus be transmitted out of the laser 101 via or through the output facet. Correspondingly, light can enter, or be transmitted into, the SOA 103 via or through the optical input facet.

In the embodiment of FIG. 6 the laser 101 and the SOA 103 lie in series such that the optical output facet of the laser 101 and the optical input facet of the SOA 103 face each other.

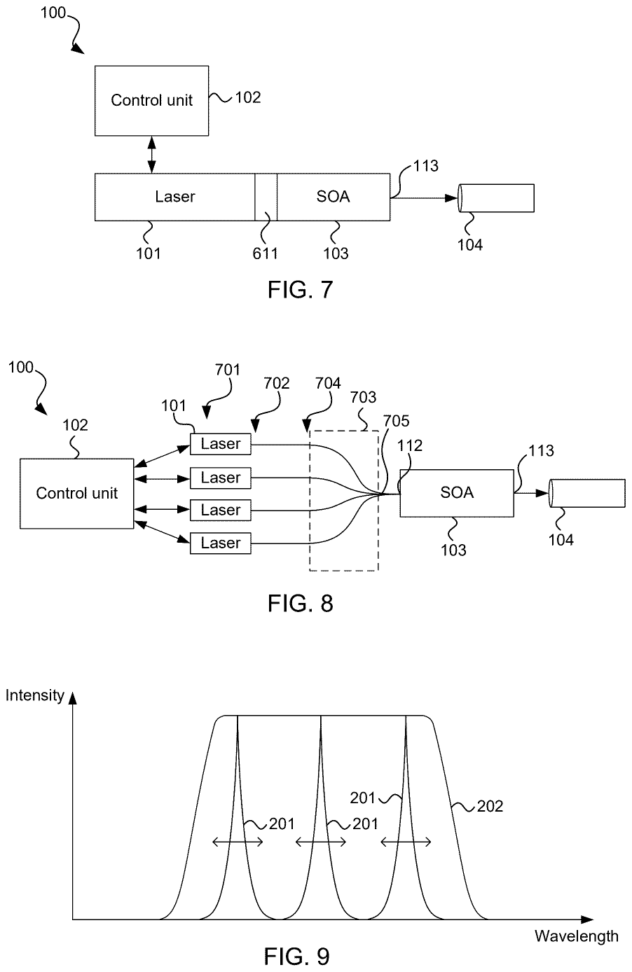

FIG. 7 illustrates a schematic representation of an optical transmitter according to another embodiment.

According to an embodiment, the optical transmitter 100 further comprises an optical isolator 611 optically coupled to the optical output of the laser and the optical input of the semiconductor optical amplifier 103.

The optical isolator 611 may be configured to receive the optical signal from the laser 101 and transmit the optical signal to the SOA 103.

The optical isolator 611 may be configured to prevent or reduce optical signals, such as reflections, from being transmitted from the SOA 103 to the laser 101.

FIG. 8 illustrates a schematic representation of an optical transmitter according to another embodiment.

According to an embodiment, the optical transmitter 100 further comprises: a laser array 701 comprising the laser 101, wherein each laser in the laser array 701 comprises an optical output 702 and is configured to provide an optical signal to the optical output 702 of the laser based on a corresponding control current and each optical signal comprises a spectral line of different wavelength.

For example, in the embodiment of FIG. 7, a laser array 701 comprising a four lasers is illustrated. In other embodiments, the laser array 701 may comprise any number of lasers, such as a plurality of lasers.

Since each optical signal can comprise a spectral line of different wavelength, each laser in the laser array 701 may be configured to emit a spectral line of a different wavelength when no modulation is applied to the laser.

The optical transmitter 100 may further comprise an optical combiner 703 comprising a plurality of optical inputs 704 and an optical output 705, wherein each optical input in the plurality of optical inputs 704 is optically coupled to the optical output 702 of a corresponding laser in the laser array 701 and the optical output 705 of the optical combiner 703 is optically coupled to the optical input 112 of the semiconductor optical amplifier 103.

The control unit 102 may be electrically coupled to each laser in the laser array 701 and configured to modulate each laser in the laser array 701 using a corresponding control current. Each control current can comprise a direct current component and a temporally varying modulation component configured to cause a temporal variation of the wavelength of the spectral line in the corresponding optical signal.

In some embodiments, the direct current component provided to each laser in the laser array 701 may be different. In some embodiments, the temporally varying modulation component provided to each laser in the laser array 701 may be different.

In some embodiments, the same direct current component may be provided to each laser in the laser array 701. In some embodiments, the same temporally varying modulation component may be provided to each laser in the laser array 701.

Each laser in the laser array 701 may be configured to emit a spectral line of a different wavelength when no modulation is applied to the laser. When modulation is applied to the laser array 701 and the wavelengths of the spectral lines in the optical signals vary temporally, the spectral lines of different lasers in the laser array 101 may still not overlap in terms of wavelength.

In some embodiments, the control currents used to modulate each laser in the laser array 701 may be synchronized. Thus, the laser array 701 may be modulated in a synchronized manner.

FIG. 9 illustrates a schematic representation of a spectrum of a laser according to another embodiment.

According to an embodiment, the laser comprises a comb laser configured to provide a plurality of spectral lines of different wavelengths in the optical signal.

The embodiment of FIG. 9 illustrates an example of a spectrum comprising a plurality of spectral lines 201. Such a spectrum may be produced by, for example, a laser array 701 or a comb laser. For example, when the optical signals from the laser array 701 are combined by the optical combiner 703, the spectrum of the output of the optical combiner 703 may comprise a plurality of spectral lines 201.

When the laser 101 or the laser array 701 is modulated using the control current(s), the temporally varying modulation component can cause the spectral lines 201 to move as illustrated by the arrows in FIG. 9.

The embodiment of FIG. 9 further illustrates an envelope 202 of the spectrum. The envelope 202 can correspond to, for example, a temporal average of the spectrum over one or more periods of the temporally varying modulation component. As the temporally varying modulation component varies over time, the spectral lines 201 move and thus the envelope 202 is formed. Thus, with the varying modulation component, broadening of the spectrum can be achieved.

With the plurality of spectral lines 201, each spectral line 201 may need to be moved less in frequency, compared to a single spectral line, in order to achieve a similar envelope wavelength width. Thus, less frequency modulation may be needed in the control current(s).

In some embodiments, the range of the wavelength modulation/sweeping can be smaller than the line spacing (distance between the adjacent spectral lines 201). In such embodiments, there may not be a continuous spectrum as illustrated in the embodiment of FIG. 9. Rather, there may be several discreet ranges for each line, while the width of each range would depend on the sweeping/modulation.

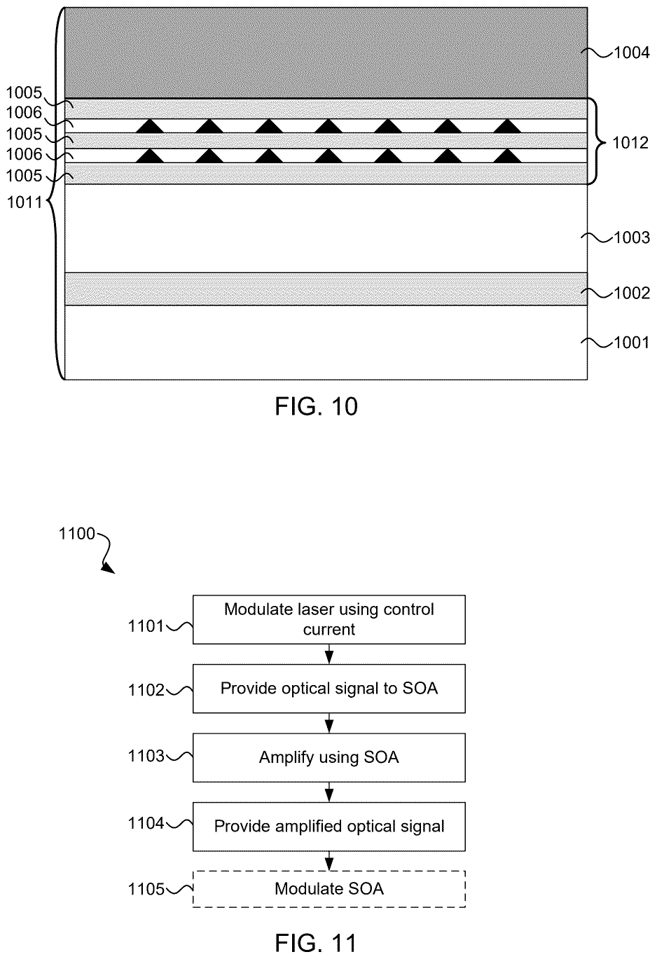

FIG. 10 illustrates a schematic representation of a semiconductor structure according to another embodiment.

According to an embodiment, the laser 101 comprises an active region comprising at least one of: quantum wells, quantum dots, quantum wires, or/and quantum dashes.

According to an embodiment, the laser 101 comprises an active region based on quantum well and/or quantum dot layers realized in III-V material composition.

Herein, a III-V material composition may refer to a material composition where at least part of the material composition comprises, or is formed of, one or more compound semiconductors of column III and column V materials, thus one or more III-V compound semiconductor materials. Examples of such III-V compound semiconductors comprise GaAs and its derivatives such as InGaAs and AlGaAs.

For example, the laser 101 and/or the SOA 103 may comprise a plurality of semiconductor layers 1011 epitaxially deposited on a substrate, wherein the plurality of semiconductor layers 1101 comprises an active region 1012.

The control current may be applied to the laser 101 by, for example, placing a metal contact on top of the plurality of semiconductor layers 1011 of the laser 101 and to the bottom of the plurality of semiconductor layers 1011 of the laser 101 and providing the control current via the metal contacts. Similarly, the bias current and/or the second control current may be applied to the SOA 103 by, for example, placing a metal contact on top of the plurality of semiconductor layers 1011 of the SOA 103 and to the bottom of the plurality of semiconductor layers 1011 of the SOA 103 and providing the bias current and/or the second control current via the metal contacts.

The plurality of semiconductor layers 1011 may also be referred to as a semiconductor heterostructure. A heterostructure may refer to a semiconductor structure comprising two or more different semiconductor materials. The different materials may form or be in the form of layers, whereby layers of different materials are superposed. A III-V compound semiconductor heterostructure may comprise, for example, a plurality of layers of different materials selected from GaAs and its derivatives.

For example, in the embodiment of FIG. 10, the plurality of semiconductor layers 1011 comprises a substrate layer 1001, such as a GaAs substrate layer, an n-type contact layer 1002, such as a layer of n-type GaAs, a bottom cladding layer 1003, such as a layer of n-type AlGaAs, the active region 1012, and a top cladding layer 1004, such as a layer of p-type AlGaAs.

The active region 1102 may be used to perform lasing of the laser 101 and/or amplification of the SOA 103.

A refractive index of the active region 1012 can be greater than a refractive index of the bottom cladding layer 1003 and a refractive index of the top cladding layer 104. The active region 1012 may be located between the bottom cladding layer 1003 and the top cladding layer 1004. By having the refractive index of the active region 1012 being greater than the refractive index of the bottom cladding layer 1003 and the refractive index of the top cladding layer 1004, the optical signal can be efficiently confined into the active region 1012.

According to an embodiment, an effective refractive index for the fundamental mode of the laser 101 at a central wavelength of 1310 nanometers is in the range of 3.3-3.4.

The embodiment of FIG. 10 illustrates a simplified example of the plurality of semiconductor layers 1011. The plurality of semiconductor layers 1011 may comprise various different layers and materials, such as those disclosed herein. The plurality of semiconductor layers 1011 may also be referred to as a semiconductor stack or similar.

According to an embodiment, the laser 101 comprises an active region 1012 comprising at least one of: quantum wells, quantum dots, quantum wires, or/and quantum dashes.

According to an embodiment, the laser 101 comprises an active region 1012 based on quantum well and/or quantum dot layers realized in III-V material composition.

According to an embodiment, the semiconductor optical amplifier 103 comprises an active region based on quantum dots embedded in quantum wells and realized in III-V material composition.

The III-V semiconductor material composition can comprise, for example, an indium phosphide (InP) based or a gallium arsenide (GaAs) based material platform. The quantum dots, quantum wells, and/or quantum dashes can be used for optical signal amplification in the SOA 103 and/or for lasing in the laser 101.

For example, the active region 1012 may comprise InGaAs QWs, InAs quantum dots (QDs).

According to an embodiment, the laser 101 comprises an active region 1012 comprising indium arsenide quantum dots embedded in indium gallium arsenide quantum wells.

According to an embodiment, the semiconductor optical amplifier 103 comprises an active region 1012 comprising indium arsenide quantum dots embedded in indium gallium arsenide quantum wells.

For example, in the embodiment of FIG. 10, the active region 1012 may comprise alternating buffer layers 1005 and InGaAs QW layers 1006 comprising InAs QDs. The alternating layers may be repeated any number of times.

The InAs QDs embedded in InGaAs QWs may also be referred to as (In, Ga)As QDs.

The InAs QDs embedded in the InGaAs QWs may be, for example, epitaxially grown.

Herein, when the plurality of semiconductor layers is realized in gallium arsenide and/or in a GaAs based material platform, GaAs may be used as the main material of the plurality of semiconductor layers 1011. For example, GaAs can be used as the substrate or some other material, such as other III-V semiconductor materials, can be used as the substrate, GaAs can be grown onto the substrate, for example epitaxially, and other structures can be grown onto the GaAs. Such a semiconductor structure may comprise, for example, a semiconductor heterostructure comprising other materials grown on the GaAs. The other materials can comprise, for example, AlAs, indium gallium arsenide (InGaAs), aluminum gallium arsenide (AlGaAs) and/or InAs.

Herein, a laser 101 capable of transmitting a plurality of spectral lines of different wavelengths in the optical signal may be referred to as a comb laser.

A laser 101 realized in a III-V semiconductor material composition comprising an active region of quantum dots, quantum wells, and/or quantum dashes may be used to implement a comb laser.

For example, the active region 1012 of the laser 101 may comprise a plurality of superposed layers of quantum dots. The quantum dots of different layers of the plurality of superposed layers of quantum dots may have different sizes to emit light at a plurality of spectral lines.

The quantum dots of the active region may have a plurality of different sizes. Quantum dots of different sizes may be distributed by the sizes thereof in different quantum dot layers.

The size of a quantum dot may affect the wavelength at which stimulated emission of light takes place at said quantum dot. Thereby, light emission in the active region comprising quantum dots of different sizes may take place at a plurality of peak wavelengths. Correspondingly, amplification of light in the active region formed by the same active layer as the active region of the laser may take place at the same plurality of peak wavelengths.

The embodiment of FIG. 10 illustrates only one example of the plurality of semiconductor layers 1011. In other embodiments, the plurality of semiconductor layers 1011 may differ from what is depicted in the embodiment.

FIG. 11 illustrates a flow chart representation of a method for transmitting an optical signal according to an embodiment.

According to an embodiment, a method 1100 for transmitting an optical signal comprises: modulating 1101 a laser using a control current, wherein the control current comprises a direct current component and a temporally varying modulation component causing a temporal variation of a wavelength of at least one spectral line in an optical signal emitted by the laser.

The modulation 1101 may be performed by, for example, the control unit 102 and the laser 101.

The method 1100 may further comprise providing 1102 the optical signal to a semiconductor optical amplifier.

The method 1100 may further comprise amplify 1103 the optical signal while operating the semiconductor optical amplifier in a saturation mode.

The method 1100 may further comprise providing 1104 the amplified optical signal to an optical fiber interface.

According to an embodiment, the method 1100 further comprises modulating 1105 the semiconductor optical amplifier using a second control current, wherein the second control current comprises a second direct current component and a second temporally varying modulation component, wherein the temporally varying modulation component has a first phase and the second temporally varying modulation component has a second phase, opposite to the first phase.

It should be appreciated that the operations of the method 1100 may be performed in various order and/or at least partially simultaneously and/or continuously and/or partially. For example, while the laser is modulated 1101, an optical signal may be provided 1102 to a semiconductor optical amplifier, an optical signal may be amplified 1103, and an amplified optical signal may be provided 1104 to the optical fiber interface.

Any disclosure herein in relation to the optical transmitter 100 may also apply to the method 1100.

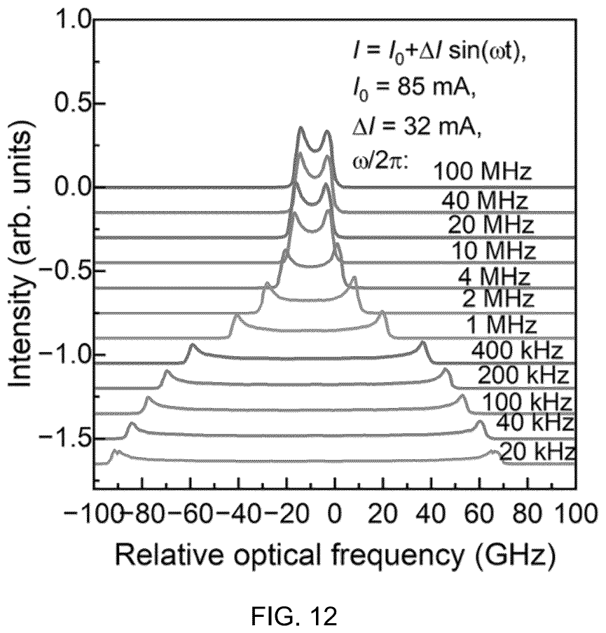

FIG. 12 illustrates a schematic representation of exemplary measurement results.

FIG. 12 illustrates spectra of the optical signals emitted by the laser 101 when the laser 101 is modulated with a control current comprising a direct current component I₀ and a temporally varying modulation component ΔIsin(ωt) . In FIG. 12, the amplitude of the direct current component is I₀=85 milliamps (mA), the amplitude of the temporally varying modulation component is ΔI=32 mA, and the frequency of the temporally varying modulation component f=ω/(2π) is varied in the range 20 kHz-100 MHz.

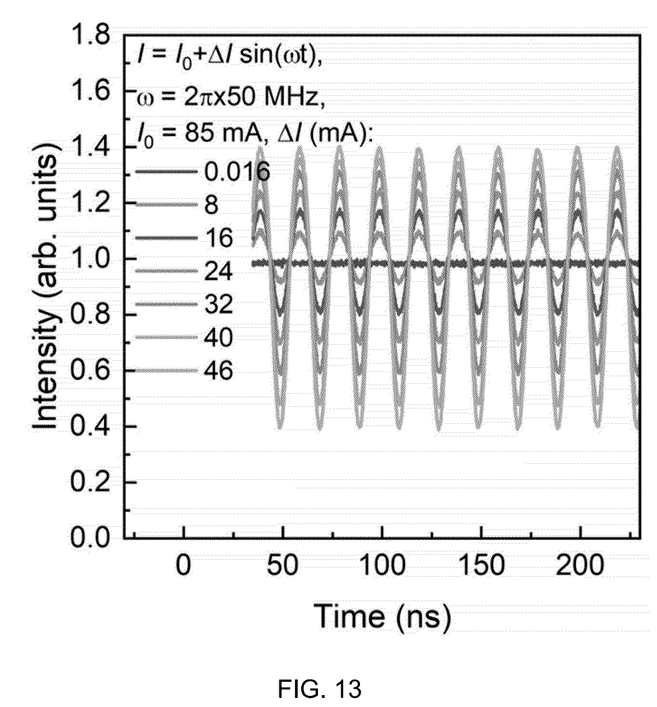

FIG. 13 illustrates a schematic representation of exemplary measurement results.

FIG. 13 illustrates the intensity variation of a single wavelength in the optical signal emitted by the laser 101 when the laser 101 is modulated with a control current comprising a direct current component I₀ and a temporally varying modulation component ΔIsin(ωt) . In FIG. 13, the amplitude of the direct current component is I₀=85 mA, the frequency of the temporally varying modulation component is f=ω/(2π)=50 MHz, and the amplitude of the temporally varying modulation component ΔI is varied in the range 0.016-46 mA.

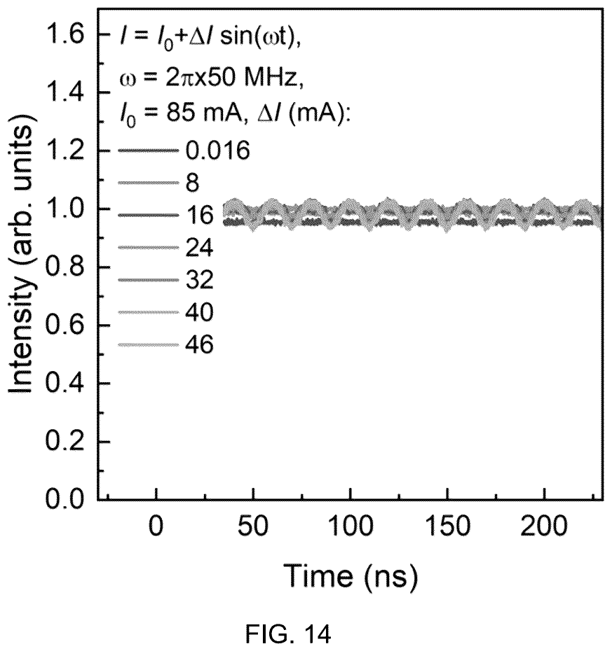

FIG. 14 illustrates a schematic representation of exemplary measurement results.

FIG. 14 illustrates the intensity variation of a single wavelength in the amplified optical signal emitted by the SOA 103 when the laser 101 is modulated with a control current comprising a direct current component I₀ and a temporally varying modulation component ΔIsin(ωt) . In FIG. 14, the same parameter values are used as in FIG. 13. As can be seen by comparing FIG. 14 and FIG. 13, intensity variation is reduced by the SOA 103.

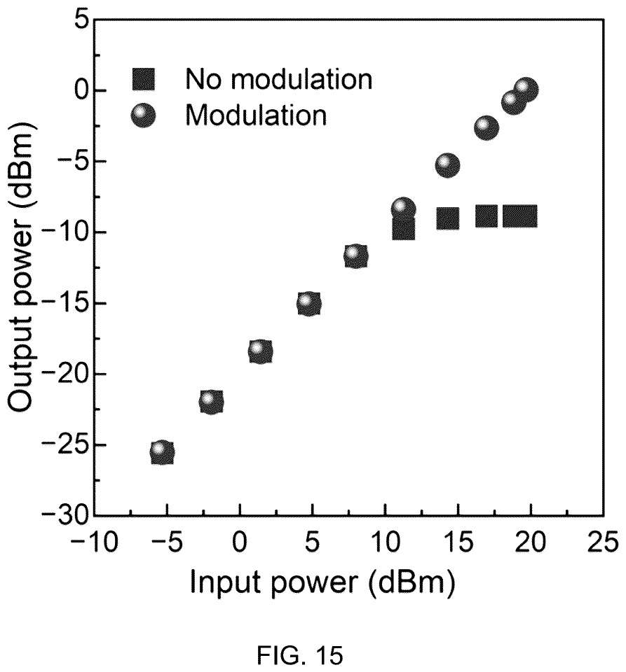

FIG. 15 illustrates a schematic representation of exemplary measurement results.

FIG. 15 illustrates the output power an optical signal outputted by an optical fiber as a function of input power of the amplified optical signal emitted by the SOA 103 to the optical fiber. Due to Brillouin scattering, without modulation applied to the laser 101, the output power saturates when an input power of approximately greater than 10 dBm is input into the optical fiber. On the other hand, when modulation is used, the output optical power does not saturate with a 10 dBm input power.

The measurement results illustrated in FIGS. 12-15 are only exemplary and may apply only for some configurations and/or parameter values. With different implementations and/or parameter values, different measurement results may be achieved.

Any range or device value given herein may be extended or altered without losing the effect sought. Also any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. An optical transmitter comprising:
a laser comprising an optical output and configured to provide an optical signal to the optical output based on a control current;
a control unit electrically coupled to the laser and configured to modulate the laser using the control current, wherein the control current comprises a direct current component and a temporally varying modulation component configured to cause a temporal variation of a wavelength of at least one spectral line in the optical signal;
a semiconductor optical amplifier comprising an optical input and an optical output, wherein the optical input of the semiconductor optical amplifier is optically coupled to the optical output of the laser and the semiconductor optical amplifier is configured to receive the optical signal from the optical output of the laser, amplify the optical signal while operating in a saturation mode, and provide the amplified optical signal to the optical output of the semiconductor optical amplifier; and
an optical fiber interface optically coupled to the optical output of the semiconductor optical amplifier.

2. The optical transmitter according to claim 1, wherein the laser comprises a single-mode laser.

3. The optical transmitter according to claim 1, wherein the laser comprises a semiconductor laser.

4. The optical transmitter according to claim 1, wherein the laser comprises a distributed feedback laser or a Fabry-Pérot laser.

5. The optical transmitter according to claim 1, wherein the laser comprises an active region comprising at least one of: quantum wells, quantum dots, quantum wires, or/and quantum dashes.

6. The optical transmitter according to claim 1, wherein the laser comprises an active region based on quantum well and/or quantum dot layers realized in III-V material composition.

7. The optical transmitter according to claim 1, wherein the semiconductor optical amplifier comprises an active region based on quantum dots embedded in quantum wells and realized in III-V material composition.

8. The optical transmitter according to claim 1, wherein the laser comprises an active region comprising indium arsenide quantum dots embedded in indium gallium arsenide quantum wells.

9. The optical transmitter according to claim 1, wherein the semiconductor optical amplifier comprises an active region comprising indium arsenide quantum dots embedded in indium gallium arsenide quantum wells.

10. The optical transmitter according to claim 1, wherein the laser further comprises a distributed Bragg reflector.

11. The optical transmitter according to claim 1, wherein the laser and the semiconductor optical amplifier are monolithically integrated.

12. The optical transmitter according to claim 1, further comprising an optical isolator optically coupled to the optical output of the laser and the optical input of the semiconductor optical amplifier.

13. The optical transmitter according to claim 1, wherein the laser comprises a comb laser configured to provide a plurality of spectral lines of different wavelengths in the optical signal.

14. The optical transmitter according to claim 1, wherein the temporally varying modulation component comprises a sinusoidal component or a sawtooth component.

15. The optical transmitter according to claim 1, wherein the control unit is further electrically coupled to the semiconductor optical amplifier and configured to modulate the semiconductor optical amplifier using a second control current, wherein the second control current comprises a second direct current component and a second temporally varying modulation component, wherein the temporally varying modulation component has a first phase and the second temporally varying modulation component has a second phase, opposite to the first phase.

16. The optical transmitter according to claim 1, further comprising:
a laser array comprising the laser, wherein each laser in the laser array comprises an optical output and is configured to provide an optical signal to the optical output of the laser based on a corresponding control current and each optical signal comprises a spectral line of different wavelength; and
an optical combiner comprising a plurality of optical inputs and an optical output, wherein each optical input in the plurality of optical inputs is optically coupled to the optical output of a corresponding laser in the laser array and the optical output of the optical combiner is optically coupled to the optical input of the semiconductor optical amplifier;
wherein the control unit electrically coupled to each laser in the laser array and configured to modulate each laser in the laser array using a corresponding control current, wherein each control current comprises a direct current component and a temporally varying modulation component configured to cause a temporal variation of the wavelength of the spectral line in the corresponding optical signal.

17. A method for transmitting an optical signal, the method comprising:
modulating a laser using a control current, wherein the control current comprises a direct current component and a temporally varying modulation component causing a temporal variation of a wavelength of at least one spectral line in an optical signal emitted by the laser;
providing the optical signal to a semiconductor optical amplifier;
amplifying the optical signal using the semiconductor optical amplifier while operating the semiconductor optical amplifier in a saturation mode; and
providing the amplified optical signal to an optical fiber interface.

18. The method according to claim 17, the method further comprising:
modulating the semiconductor optical amplifier using a second control current, wherein the second control current comprises a second direct current component and a second temporally varying modulation component, wherein the temporally varying modulation component has a first phase and the second temporally varying modulation component has a second phase, opposite to the first phase.
